(19) United States
(12) Patent Application Publication
(10) Pub. No.: US 2019/0331514 A1
(43) Pub. Date: Oct. 31, 2019

(54) A THERMAL FLUID FLOW SENSOR

(71) Applicant: Cambridge Enterprise Limited, Cambridge (GB)

(72) Inventors: Andrea DE LUCA, Cambridge (GB); Florin UDREA, Cambridge (GB)

(21) Appl. No.: 16/478,568

(22) PCT Filed: Dec. 19, 2017
(86) PCT No.: PCT/GB2017/053800

§ 371 Date: Jul. 17, 2019

(30) Foreign Application Priority Data
Jan. 17, 2017 (GB) 1700796.4

(51) Int. Cl. G01F 1/688; G01F 1/684; G01F 1/698; G01F 15/02; H01L 35/32

(52) U.S. Cl. CPC G01F 1/6888; G01F 1/6845; G01K 7/015; G01F 15/022; H01L 35/325; G01F 1/6986

(57) ABSTRACT

We disclose herein a CMOS-based flow sensor comprising a substrate comprising an etched portion; a dielectric region located on the substrate, wherein the dielectric region comprises a dielectric membrane over an area of the etched portion of the substrate; a p-n junction type device formed within the dielectric membrane, wherein the p-n junction type device is configured to operate as a temperature sensing device.

### FIELD OF THE INVENTION

This invention relates to a flow sensor, particularly but not exclusively, to a micromachined CMOS thermal fluid flow sensor employing a p-n junction type device operating as a temperature sensing device.

### BACKGROUND OF THE INVENTION

Thermal fluid flow sensors rely on the thermal interaction between the sensor itself and the fluid. Depending upon the physical phenomena governing the interaction, flow sensors can be can be classified into the following three categories: (i) anemometric sensors measure the convective heat transfer induced by fluid flow passing over a heated element; (ii) calorimetric sensors detect the asymmetry of the temperature profile generated by a heated element and caused by the forced convection of the fluid flow; (iii) time of flight (ToF) sensors measure the time elapsed between the application and the sensing of a heat pulse. Detailed reviews of thermal fluid flow sensor have been published (B. Van Oudheusden, “Silicon flow sensors,” in Control Theory and Applications, IEE Proceedings D, 1988, pp. 373-380; B. Van Oudheusden, “Silicon thermal flow sensors,” Sensors and Actuators A: Physical, vol. 30, pp. 5-26, 1992; N. Nguyen, “Micromachined flow sensors-A review,” Flow measurement and Instrumentation, vol. 8, pp. 7-16, 1997; Y.-H. Wang et al., “MEMS-based gas flow sensors,” Microfluidics and nanofluidics, vol. 6, pp. 333-346, 2009; J. T. Kuo et al., “Micromachined Thermal Flow Sensors-A Review,” Micromachines, vol. 3, pp. 550-573, 2012). Further background can also be found in U.S. Pat. No. 6,460,411 by Kersjes et al.

In A. Van Putten and S. Middelhoek, “Integrated silicon anemometer,” Electronics Letters, vol. 10, pp. 425-426, 1974 and A. Van Putten, “An integrated silicon double bridge anemometer,” Sensors and Actuators, vol. 4, pp. 387-396, 1983 resistor based anemometers are integrated on chip within Wheatstone bridge configurations. B. Van Oudheusden and J. Huijsing, “Integrated flow friction sensor,” Sensors and Actuators, vol. 15, pp. 135-144, 1988 propose a thermal flow sensor, calibrated for friction measurements, wherein thermocouples in addition to heating resistors and an ambient temperature monitoring transistor are integrated on chip. J. H. Huijsing et al., “Monolithic integrated direction-sensitive flow sensor,” Electron Devices, IEEE Transactions on, vol. 29, pp. 133-136, 1982, W. S. Kuklinski et al., “Integrated-circuit bipolar transistor array for fluid-velocity measurements,” Medical and Biological Engineering and Computing, vol. 19, pp. 662-664, 1981, U.S. Pat. No. 3,992,940 by Platzer and T. Qin-Yi and H. Jin-Biao, “A novel CMOS flow sensor with constant chip temperature (CCT) operation,” Sensors and actuators, vol. 12, pp. 9-21, 1987 are examples of transistor based anemometers. The main drawback of all the previously mentioned citations resides in the lack of an effective thermal isolation of the heated element, which results in high power dissipation, low sensitivity and slow dynamic response of the sensor.

In D. Moser et al., “Silicon gas flow sensors using industrial CMOS and bipolar IC technology,” Sensors and Actuators A: Physical, vol. 27, pp. 577-581, 1991 an array of seven npn transistors are used as heating elements and suspended on a crystal silicon cantilever beam for effective thermal isolation. An ordinary pn diode measures the temperature on the beam. The voltage across nineteen silicon/aluminium thermocouples, with hot junctions on the beam and cold junctions on the substrate, is correlated to the gas flow velocity while the heater is driven at constant power. The issue associated with the use of a cantilever structure is that they suffer from mechanical fragility and vibration sensitivity.

Similarly, L. Lofdahl et al., “A sensor based on silicon technology for turbulence measurements,” Journal of Physics E: Scientific Instruments, vol. 22, p. 391, 1989 present a heating resistor and a heater temperature sensing diode integrated on a cantilever beam. Polyimide is used as thermal isolation material between the beam and the substrate. The use of polyimide, although improving the beam thermal isolation, further affects the mechanical robustness of the beam.

In R. Kersjes et al., “An integrated sensor for invasive blood-velocity measurement,” Sensors and Actuators A: Physical, vol. 37, pp. 674-678, 1993 a polysilicon heater, driven at constant heating power, and a first diode, used for heater temperature monitoring, are placed on a silicon membrane. A second diode is placed on the substrate for ambient temperature monitoring. A similar sensor is also presented in A. Van der Wiel et al., “A liquid velocity sensor based on the hot-wire principle,” Sensors and Actuators A: Physical, vol. 37, pp. 693-697, 1993, where more transistors, in diode configuration, are connected in series in order to improve the temperature sensitivity of the sensor. The use of silicon as membrane material is not ideal due to the high thermal conductivity of the silicon layer. This results in high power dissipation, low sensitivity and slow dynamic response of the sensor.

In U.S. Pat. No. 6,460,411, by Kersjes et al., a silicon membrane perforated by slots of thermally insulating material is proposed as a solution to mitigate power dissipation, sensitivity and dynamic response issues, at the expenses of a more complex fabrication process, still without completely removing the silicon from the membrane.

In US20160216144A1 a CMOS flow sensor is disclosed, comprising a heating element and a number of thermocouples. Interestingly the heating element and the sensing junction of the thermocouples are thermally isolated by a dielectric membrane. However, the thermocouples still provide an additional thermal dissipation path within the membrane, thus increasing the power dissipation, lowering the sensitivity and slowing down the dynamic response of the sensor.

In E. Yoon and K. D. Wise, “An integrated mass flow sensor with on-chip CMOS interface circuitry,” Electron Devices, IEEE Transactions on, vol. 39, pp. 1376-1386, 1992 a multimeasurand flow sensor is proposed. The sensor is capable of measuring flow velocity, flow direction, temperature and pressure. It also has flow discrimination capabilities. Everything is integrated with on-chip circuitry. Thermal isolation of the hot elements is provided via a dielectric membrane. However, gold is used and this make the process not fully CMOS compatible, and thus more expensive than a fully CMOS process.

N. Sabaté et al., “Multi-range silicon micromachined flow sensor,” Sensors and Actuators A: Physical, vol. 110, pp. 282-288, 2004 present a multirange flow sensor using nickel resistors as temperature sensors positioned at different distances from the nickel resistive heater. Nickel is not a standard CMOS material, making the sensor fabrication process more expensive than a fully CMOS process.

### SUMMARY

It is an object of this invention to provide a CMOS flow sensor (a micromachined CMOS thermal fluid flow sensor), more in particular to a device for measuring the variations of heat exchange between the device itself and the environment by means of p-n junction type devices.

Aspects and preferred features are set out in the accompanying claims.

We disclose herein a CMOS-based flow sensor comprising: a substrate comprising an etched portion; a dielectric region located on the substrate, wherein the dielectric region comprises a dielectric membrane over an area of the etched portion of the substrate; a p-n junction type device formed within the dielectric membrane, wherein the p-n junction type device is configured to operate as a temperature sensing device. Advantageously the device is configured to measure the variations of heat exchange between the device itself and the environment by means of p-n junction type devices. The arrangement is also configured to provide an improved thermal isolation for the flow sensor.

The starting substrate may be silicon, or silicon on insulator (SOI). However, any other substrate combining silicon with another semiconducting material compatible with state-of-the-art CMOS fabrication processes may be used. Employment of CMOS fabrication processes guarantees sensor manufacturability in high volume, low cost, high reproducibility and wide availability of foundries supporting the process. CMOS processes also enable on-chip circuitry for sensor performance enhancement and system integration facilitation.

The dielectric membrane or membranes may be formed by back-etching using Deep Reactive Ion Etching (DRIE) of the substrate, which results in vertical sidewalls and thus enabling a reduction in sensor size and costs. However, the back-etching can also be done by using anisotropic etching such as KOH (Potassium Hydroxide) or TMAH (TetraMethyl Ammonium Hydroxide) which results in slopping sidewalls. The membrane can also be formed by a front-side etch or a combination of a front-side and back-side etch to result in a suspended membrane structure, supported only by 2 or more beams. The membrane may be circular, rectangular, or rectangular shaped with rounded corners to reduce the stresses in the corners, but other shapes are possible as well.

The dielectric membrane may comprise silicon dioxide and/or silicon nitride. The membrane may also comprise one or more layers of spin on glass, and a passivation layer over the one or more dielectric layers. The employment of materials with low thermal conductivity (e.g. dielectrics) enables a significant reduction in power dissipation as well as an increase in the temperature gradients within the membrane with direct benefits in terms of sensor performance (e.g. sensitivity, frequency response, range, etc.).

The membrane may also have other structures made of polysilicon, single crystal silicon or metal. These structures can be embedded within the membrane, or maybe above or below the membrane, to engineer the thermo-mechanical properties (e.g. stiffness, temperature profile distribution, etc.) of the membrane and/or the fluid dynamic interaction between the fluid and the membrane. More generally these structures can be also outside the membrane and/or bridging between inside and outside the membrane.

The p-n junction type device, formed within the dielectric membrane, may be a diode or an array of diodes for enhanced sensitivity and located in the area of the membrane having the highest thermal isolation towards the substrate. The diode may be made of polysilicon or of single crystal silicon.

The p-n junction type device may also be a three terminal device, i.e. a transistor. The transistor may have an accessible gate or base contact or may have the gate/base shorted to one of the other two terminals. For example an npn transistor with the base shorted to the collector can become a p-n diode. More transistors may also be put in array form. The p-n junction type device may also be any other type of devices having at least one p-n junction.

The p-n junction type device is configured to operate as a temperature sensing device. Reference p-n junction type devices that measure the substrate/case/ambient temperature can be placed outside the membrane area and used for compensation purposes. Any of the p-n junction type devices may also be part of a more complex temperature sensing circuit, such as a VPTAT (voltage proportional to absolute temperature) or IPTAT (current proportional to absolute temperature).

According to one embodiment, the p-n junction type device can also be used as a heating element as well as temperature sensing device at the same time. Injection of a current into the p-n junction type device formed within the dielectric membrane results in a localised increase in temperature. The heat exchange between the p-n junction type device and the fluid can then be measured through the p-n junction type device itself and correlated to the at least one property of the fluid (e.g. velocity, flow rate, exerted wall shear stress, pressure, temperature, direction, thermal conductivity, diffusion coefficient, density, specific heat, kinematic viscosity, etc.). Sensing of such fluid properties can enable fluid discrimination (or differentiation). For instance, the flow sensor can sense if the fluid is in gas form or liquid form, or the sensor can discriminate between different fluids (e.g. between air and CO₂), or if the fluid is a mixture the sensor can measure the mixture ratio. Both qualitative (e.g. liquid or gas form) and quantitative information (e.g. gas concentration) of the fluid properties can be obtained.

In one embodiment, an additional heating element is formed within the dielectric membrane, and may be made of tungsten. Tungsten is highly electromigration resistant and permits a high current density, thus reliably reaching temperature in excess of 600° C. The heating element can also be made of single crystal silicon (n-type doped, p-type doped or un-doped), polysilicon (n-type doped, p-type doped or un-doped), aluminium, titanium, silicides or any other metal or semi-conductive material available in a state-of-the-art CMOS process. The heating element can be provided with both amperometric and voltammetric connections allowing 4-wire type measurement of its resistance. Injection of a current into the resistive heating element results in a localised increase in temperature. The heat exchange between the heating element and the fluid can then be measured through the p-n junction type device and correlated to the at least one property of the fluid. Advantageously the p-n type device can be made very small and placed right underneath the resistive heating element in the area of the membrane having the highest increase in temperature, resulting in increased performance of the sensor (e.g. sensitivity, frequency response, range, etc.).

The p-n junction may be operated in the forward bias mode where the forward voltage across the diode decreases linearly with the temperature (for silicon this slope is −1 to 2 mV/° C.) when operated at constant forward current, or can be operated in the reverse bias mode where the leakage is exponentially dependent on temperature. The former method may be the preferred method because of the linearity and the precision and reproducibility of the forward voltage mode. The latter may have higher sensitivity, but the leakage current is less reproducible from one device to another or from one lot of devices to another.

The heater and the p-n junction type device may be operated in a pulse mode (e.g. driven with a square wave, sinusoidal wave, Pulse Width Modulated wave, etc.) or continuous mode. The pulse mode has, among others, the advantage of reduced power consumption, reduced electromigration for enhanced device reliability/lifetime and improved fluid properties sensing capabilities.

In one embodiment, one or more additional thermopiles may be used as temperature sensing elements. A thermopile comprises one or more thermocouples connected in series. Each thermocouple may comprise two dissimilar materials which form a junction at a first region of the membrane, while the other ends of the materials form a junction at a second region of the membrane or in the heat sink region (substrate outside the membrane area), where they are connected electrically to the adjacent thermocouple or to pads for external readout.

The thermocouple materials may comprise a metal such as aluminum, tungsten, titanium or combination of those or any other metal available in a state-of-the-art CMOS process, doped polysilicon (n or p type) or doped single crystal silicon (n or p type). In the case that both the materials are polysilicon and/or single crystal silicon, a metal link might be used to form the junctions between them.

The position of each junction of a thermocouple and the number and the shape of the thermocouples may be any required to adequately map the temperature profile distribution over the membrane to achieve a specific performance.

In one embodiment, one or more temperature sensing elements (p-n junction type device or thermocouple) and one or more heating elements are embedded within the membrane. The choice of the shape, position and number of temperature sensing elements and heating elements can be any required to adequately generate the temperature profile and/or map the temperature profile distribution over the membrane to achieve a specific performance, and can result in multi-directional, multi-range, multi-properties sensing capabilities. For instance the flow sensor may be designed to sense both flow rate and flow direction, or flow rate, flow direction and fluid thermal conductivity, or any other combination of fluid properties.

Additionally, redundancy of temperature sensing elements and/or heating elements may be used to improve the reliability/life time of the flow sensor and/or for integrity assessment. For instance, in a first case where only a first temperature sensing element is needed for flow sensing, a second temperature sensing element may be used to recalibrate the first temperature sensing element or used in place of the first temperature sensing element when aging of the first temperature sensing element occurs. In a second case, where only a first heating element is needed for flow sensing, a second heating element may be used to recalibrate the first heating element or used in place of the first heating element when aging of the first heating element occurs.

In one embodiment, the substrate may comprise: more than one etched portion; a dielectric region located on the substrate, wherein the dielectric region comprises a dielectric membrane over each area of the etched portion of the substrate. At least one membrane contains any combination of the features described in the previous embodiments. An adequate choice of the features can result in multi-directional, multi-range, multi-properties sensing capabilities. For instance the flow sensor may be designed to have a first membrane containing features to sense flow rate and a second membrane containing features to sense flow direction, or a first membrane containing features to sense flow rate and flow direction and a second membrane containing features to sense fluid thermal conductivity. Any other combination of fluid properties is also possible.

The flow sensor, in addition to the at least one membrane containing any combination of the features described in the previous embodiments, may also be designed to have one or more additional membranes used as pressure sensors. Membrane based pressure sensors are well known and relies on piezo-elements (e.g. piezo-resistors, piezo-diodes, piezo-FET, etc.) to have an electric signal proportional to the displacement of the membrane after a pressure is applied. The pressure sensing membrane may be also used for pressure compensation purposes, to improve the flow sensor performance (e.g. sensitivity, range, dynamic response, etc.), to increase the flow sensor reliability/life time and/or for integrity assessment.

In one embodiment, analogue/digital circuitry may be integrated on-chip. Circuitry may comprise IPTAT, VPTAT, amplifiers, analogue to digital converters, memories, RF communication circuits, timing blocks, filters or any other mean to drive the heating element, read out from the temperature sensing elements or electronically manipulate the sensor signals. For example, it is demonstrated that a heating element driven in constant temperature mode results in enhanced performance and having on-chip means to implement this driving method would result in a significant advancement of the state-of-the-art flow sensors. Also the driving method known a 3w may be implemented via on-chip means, or any other driving method, such as constant temperature difference and time of flight, needed to achieve specific performance (e.g. power dissipation, sensitivity, dynamic response, range, fluid property detection, etc.). In absence of on-chip circuitry, this disclosure also covers the off-chip implementation of such circuital blocks when applied to a flow sensor having one or more features described in any of the previous embodiments. Such off-chip implementation may be done in an ASIC or by discrete components, or a mix of the two.

The device may be packaged in a metal TO type package, in a ceramic, metal or plastic SMD (surface mount device) package. The device may also be packaged directly on a PCB, or be packaged in a flip-chip method. The device may also be embedded in a substrate, such as a customised version of one of the previously mentioned package, a rigid PCB, a semi-rigid PCB, flexible PCB, or any other substrate, in order to have the device surface flush with the substrate surface. The device membrane may be hermetically or semi-hermetically sealed with a gas (e.g. air, dry air, argon, nitrogen, xenon or any other gas) or a liquid, to engineer the thermo-mechanical properties of the device. The device may also be packaged in a vacuum. The package can also be a chip or wafer level package, formed for example by wafer-bonding.

The flow sensor may have through silicon vias (TSV), to avoid the presence of bond wires in proximity of the sensitive area of the device which might affect the flow sensor readings. Advantageously, a flow sensor with TSV can enable 3D stacking techniques. For instance the flow sensor chip can sit on top of an ASIC, thus reducing the sensor system size.

The flow sensor may be used in applications ranging from smart energy (e.g. HVAC, white goods, gas metering) and industrial automation (e.g. leakage testing, dispensing, analytic instruments) to medical (e.g. spirometry, capnometry, respirators, inhalers, drug delivery) and fluid dynamics research (e.g. turbulence measurements, flow attachment). Interestingly, this invention also enables application in harsh environments (ambient temperature from cryogenic regime up to 300° C.), such as boilers, automotive, space and others.

We also disclose herein a method of manufacturing a CMOS-based flow sensor, the method comprising: forming at least one dielectric membrane on a substrate comprising an etched portion, wherein the dielectric membrane is over an area of the etched portion of the substrate; and forming a p-n junction type device within the at least one dielectric membrane, wherein the p-n junction type device operates as a temperature sensing device.

### BRIEF DESCRIPTION OF THE PREFERRED EMBODIMENTS

Some preferred embodiments of the invention will now be described by way of example only and with reference to the accompanying drawings, in which:

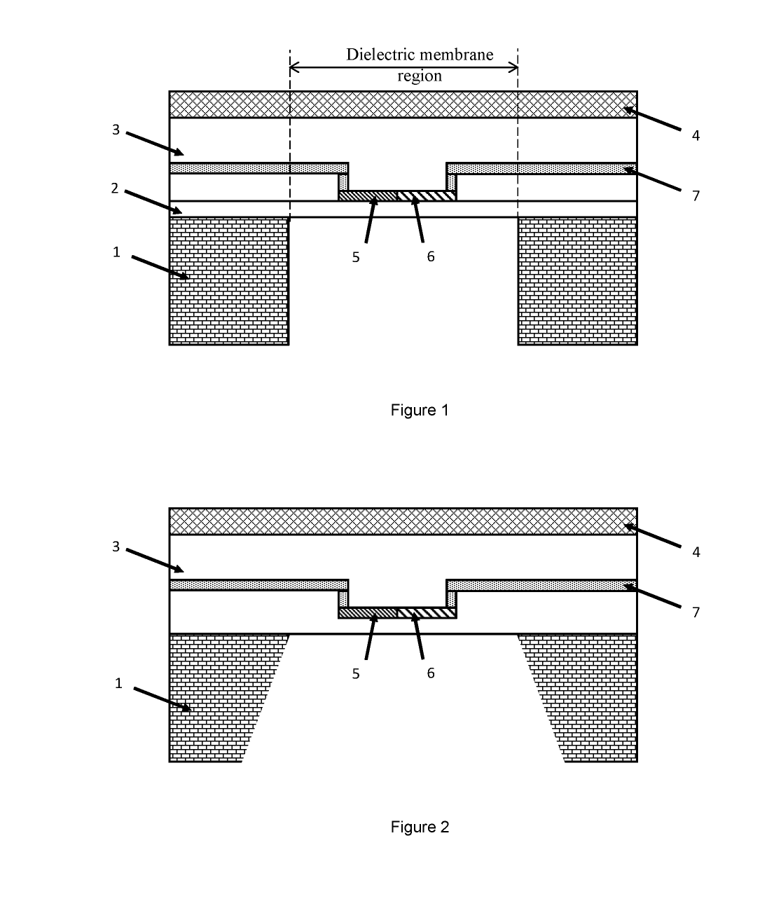

FIG. 1 shows a schematic cross-section of a SOI CMOS flow sensor, having a diode embedded within a portion of the substrate (i.e. a membrane) etched by DRIE resulting in vertical sidewalls;

FIG. 2 shows a schematic cross-section of a CMOS flow sensor, having a diode embedded within a portion of the substrate (i.e. a membrane) etched by wet etching resulting in slanted sidewalls;

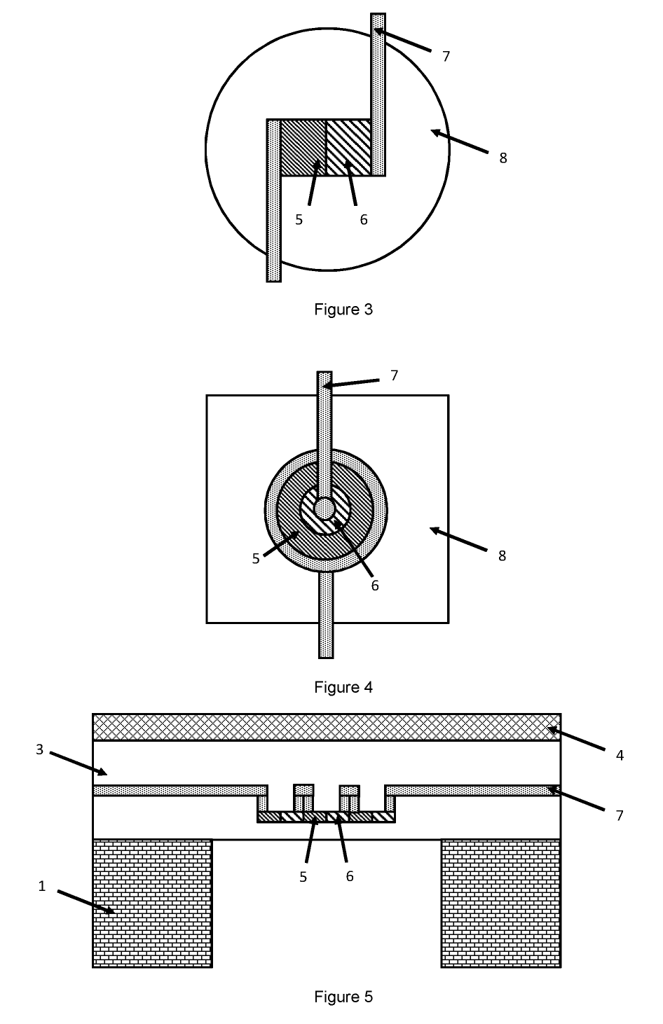

FIG. 3 shows a schematic top view of a rectangular diode embedded within a circular membrane;

FIG. 4 shows a schematic top view of a circular diode embedded within a square membrane;

FIG. 5 shows a schematic cross-section of a CMOS flow sensor, having three diodes in series embedded within a membrane;

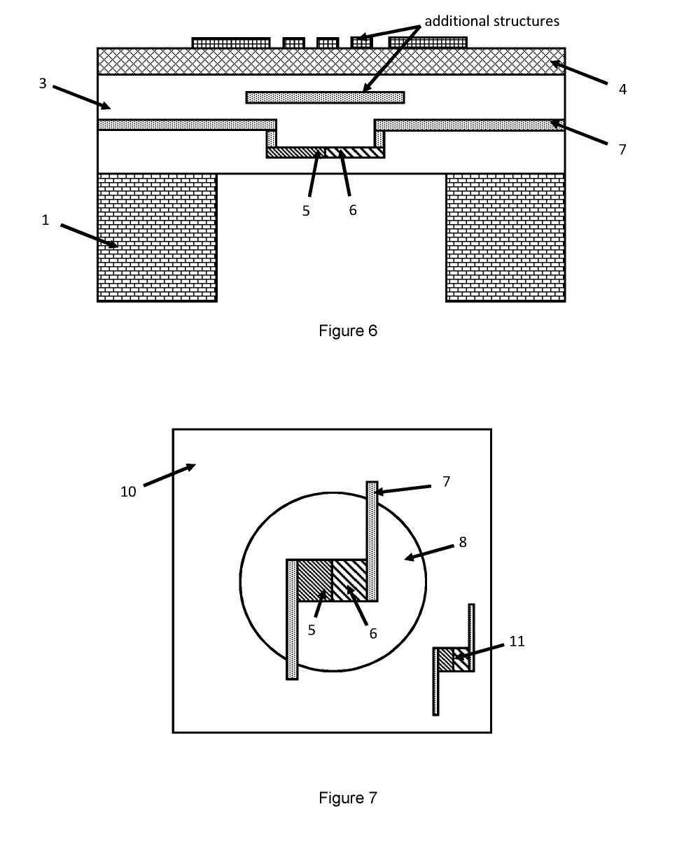

FIG. 6 shows a schematic cross-section of a CMOS flow sensor, having a diode embedded within a membrane as well as additional structures within and above the dielectric region;

FIG. 7 shows a schematic top view of a CMOS flow sensor chip, having a diode embedded within a membrane as well as a reference diode on the substrate;

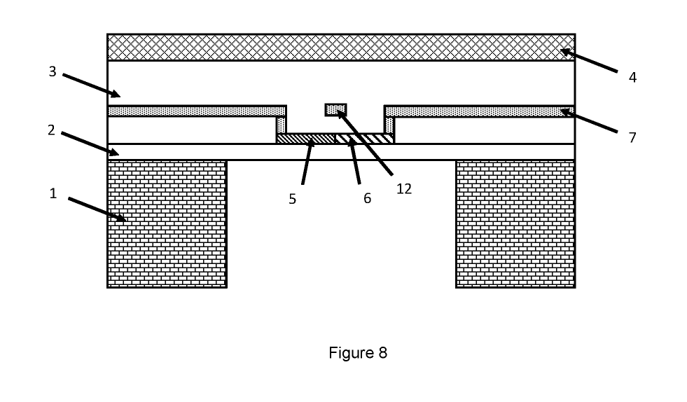

FIG. 8 shows a schematic cross-section of a SOI CMOS flow sensor, having a diode and a heating element embedded within a membrane;

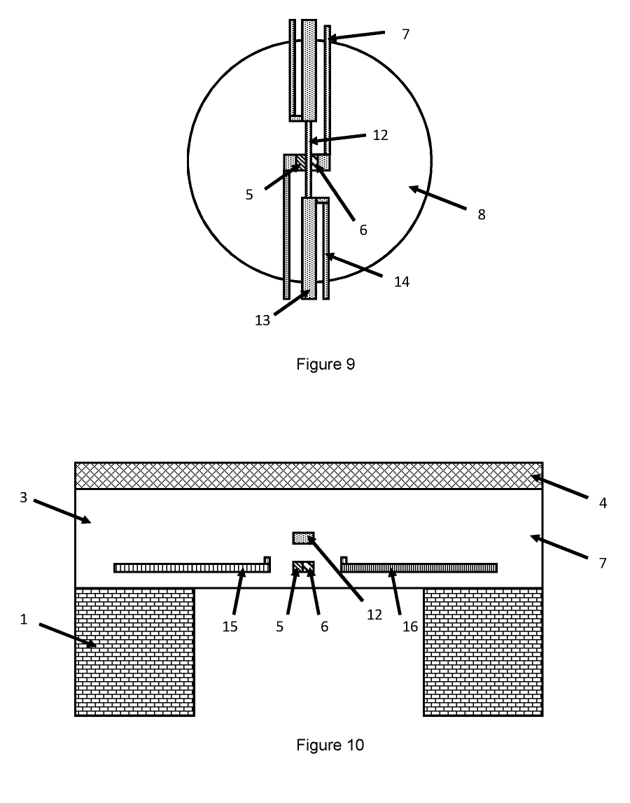

FIG. 9 shows a schematic top view of a diode embedded within a membrane underneath a wire-type heating element;

FIG. 10 shows a schematic cross-section of a CMOS flow sensor, having a diode embedded within a membrane underneath a heating element along with thermocouples;

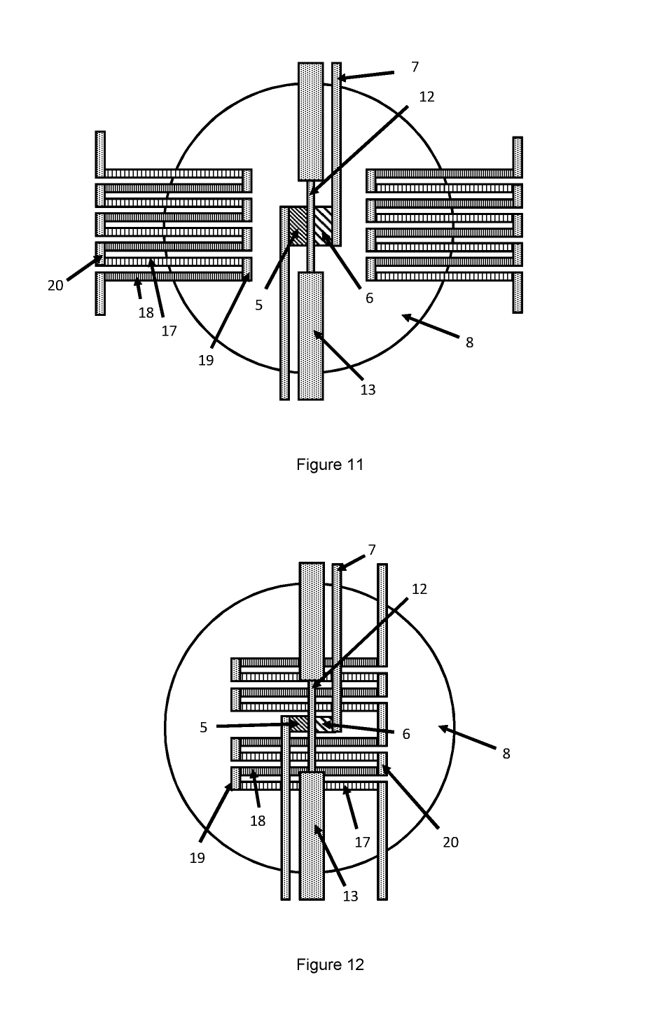

FIG. 11 shows a schematic top view of a diode embedded within a membrane underneath a heating element along with two thermopiles with reference junctions on the substrate;

FIG. 12 shows a schematic top view of a diode embedded within a membrane underneath a heating element along with a thermopile with both junctions within the membrane;

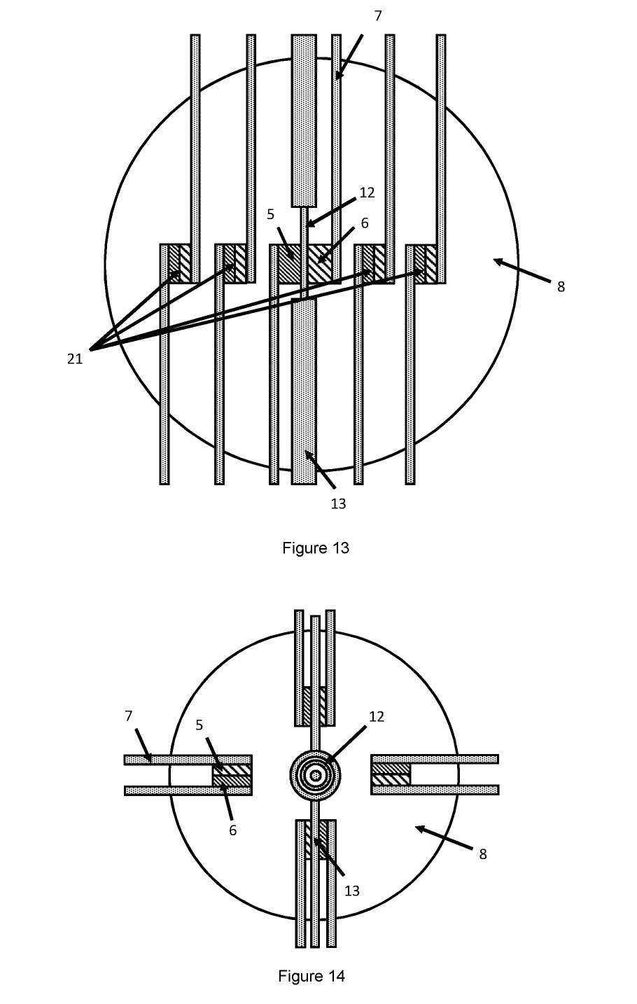

FIG. 13 shows a schematic top view of a diode embedded within a membrane underneath a heating element along with additional diodes;

FIG. 14 shows a schematic top view of a multi ring type heating element within a membrane along with additional diodes;

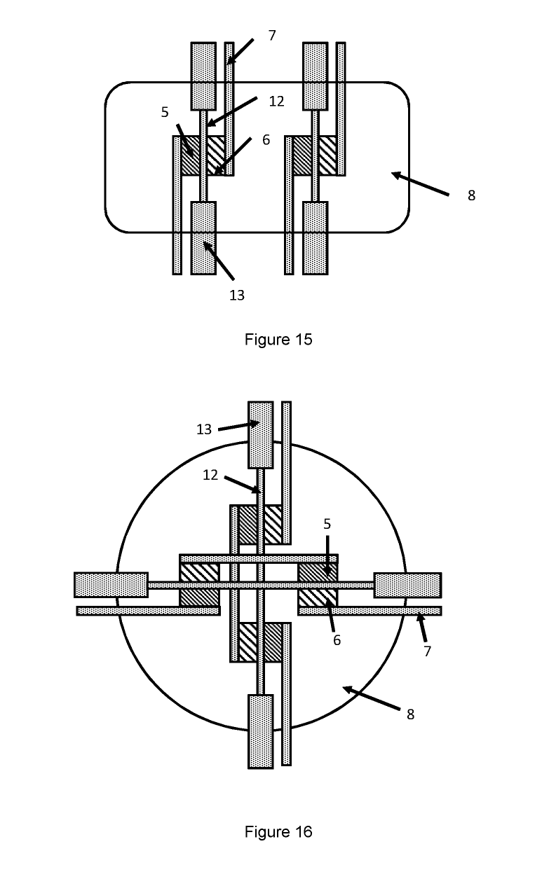

FIG. 15 shows a schematic top view of two diodes embedded within a membrane, each underneath a heating element;

FIG. 16 shows a schematic top view of two arrays of diodes embedded within a membrane, each underneath a heating element in a cross-like arrangement;

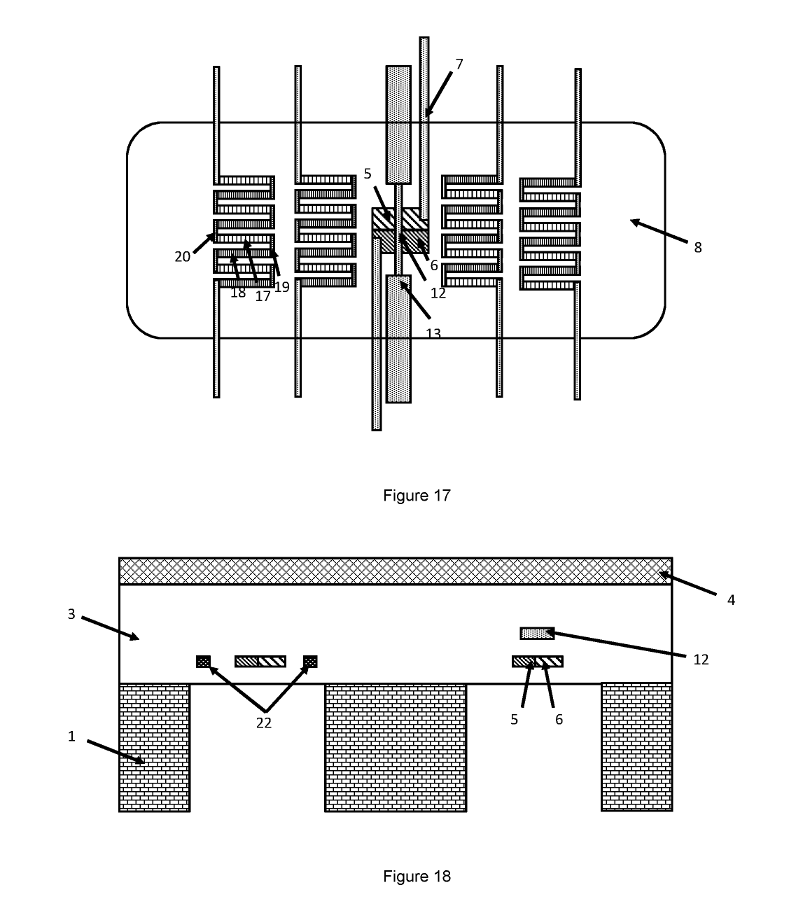

FIG. 17 shows a schematic top view of a diode embedded within a membrane underneath a heating element along with additional thermopiles;

FIG. 18 shows a schematic cross-section of a double membrane CMOS multi sensor chip;

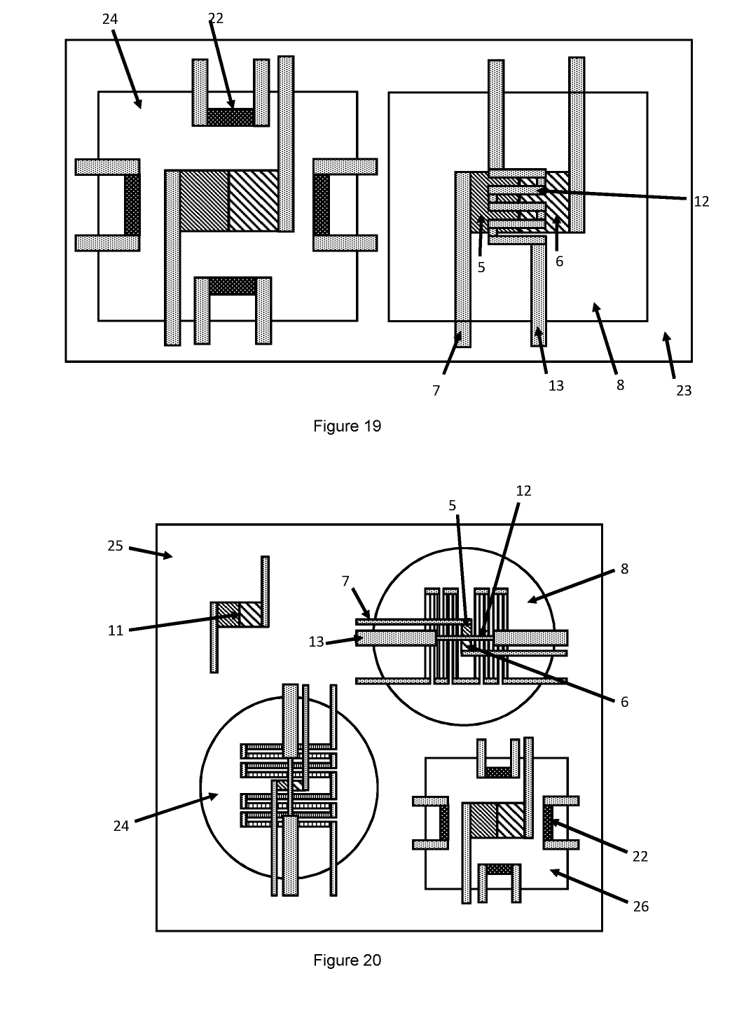

FIG. 19 shows a schematic top view of a double membrane CMOS multi sensor chip;

FIG. 20 shows a schematic top view of a multi membrane CMOS multi sensor chip;

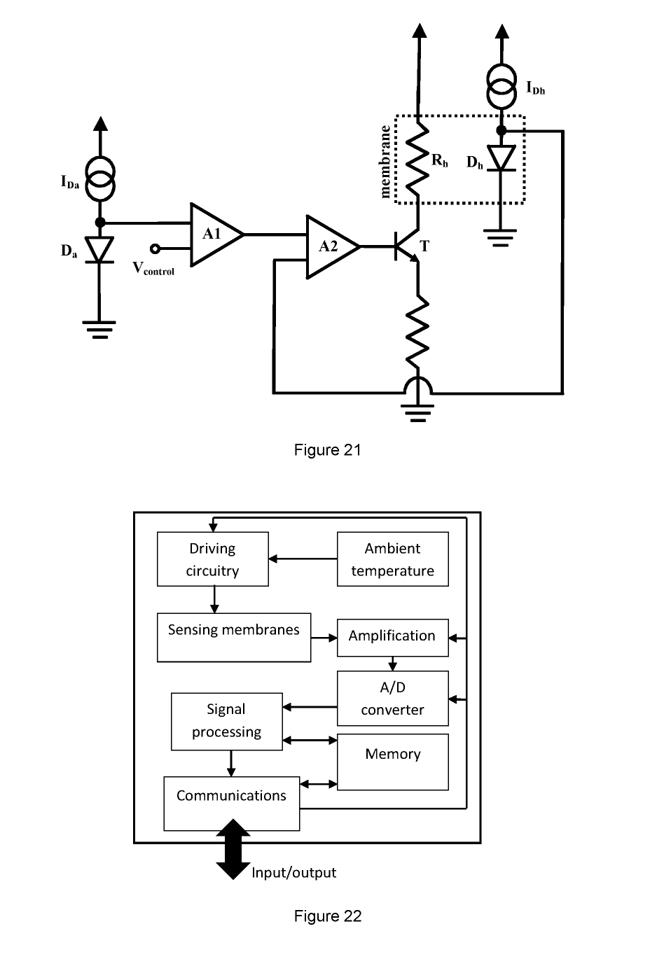

FIG. 21 is an example of circuit implementing Constant Temperature Difference driving method using diodes for thermal feedback;

FIG. 22 is an example of circuital blocks that could be monolithically integrated on-chip;

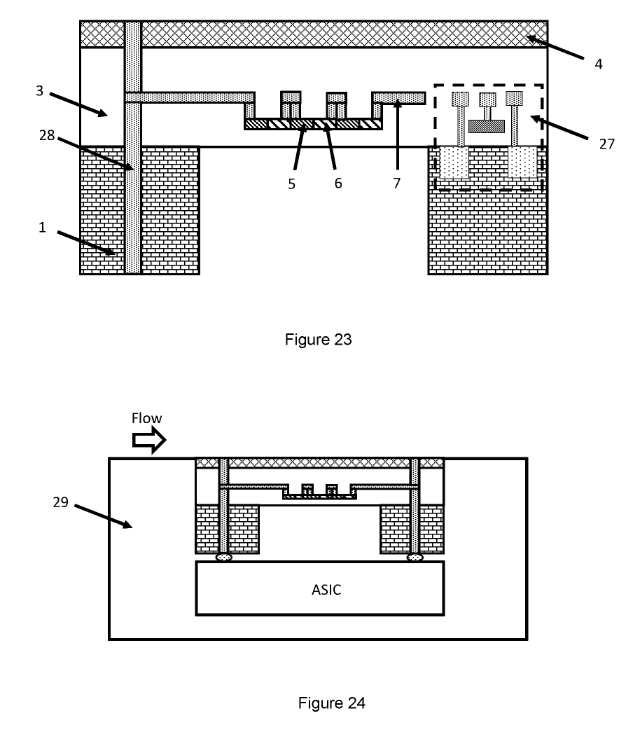

FIG. 23 shows a schematic cross-section of a CMOS flow sensor, having: three diodes in series embedded within a membrane; circuits integrated on-chip; and through silicon vias (TSV);

FIG. 24 is an example of flow sensor, 3D stacked on an ASIC embedded within a PCB, with its surface flush with the PCB surface;

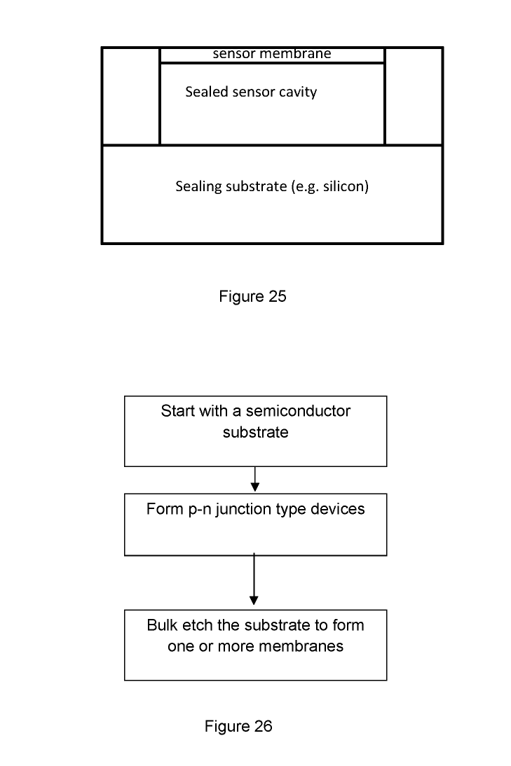

FIG. 25 is an example of sensor chip, having a sealed membrane cavity;

FIG. 26 illustrates an exemplary flow diagram outlining the manufacturing method of the flow sensor.

### DETAILED DESCRIPTION OF THE PREFERRED EMBODIMENTS

FIG. 1 shows a schematic cross section of a SOI CMOS flow sensor comprising a substrate 1 comprising an etched portion obtained by dry etching and resulting in vertical sidewalls; a dielectric region located on the substrate comprising a first dielectric layer 2 (in a SOI process this is usually referred to as buried oxide layer, BOX), a second dielectric layer 3, and a passivation layer 4. The dielectric region located on the substrate also comprises a membrane over an area of the etched portion of the substrate. In FIG. 1, the membrane region is shown using two dashed-line boundaries within the dielectric region. The same definition applies in the remaining figures. The flow sensor also comprises a p-n junction type device formed within the dielectric membrane, wherein the p-n junction type device is a diode and comprises a p region 5 and an n region 6. The diode is connected to metal tracks 7 for external access, and is configured to operate as a temperature sensing device. The diode can also be configured to operate as a heating element.

FIG. 2 shows a schematic cross section of a CMOS flow sensor comprising: a substrate 1 comprising an etched portion obtained by wet etching and resulting in slanted sidewalls; a dielectric region located on the substrate comprising a first dielectric layer 3, and a passivation layer 4. The dielectric region located on the substrate also comprises a membrane over an area of the etched portion of the substrate. The flow sensor also comprises a p-n junction type device formed within the dielectric membrane, wherein the p-n junction type device is a diode and comprises a p region 5 and an n region 6. The diode is connected to metal tracks 7 for external access, and is configured to operate as a temperature sensing device. The diode can also be configured to operate as a heating element.

FIG. 3 shows a schematic top view of a rectangular diode comprising a p region 5 and an n region 6 embedded within a circular membrane 8. The membrane region 9 is the entire area within the perimeter of the circle. The diode is connected to metal tracks 7 for external access, and is configured to operate as a temperature sensing device. The diode can also be configured to operate as a heating element.

FIG. 4 shows a schematic top view of a circular diode comprising a p region 5 and an n region 6 embedded within a square membrane 8. In this example, the membrane region 9 is the entire area within the square. The diode is connected to metal tracks 7 for external access, and is configured to operate as a temperature sensing device. The diode can also be configured to operate as a heating element.

FIG. 5 shows a schematic cross section of a CMOS flow sensor comprising: a substrate 1 comprising an etched portion obtained by dry etching and resulting in vertical sidewalls; a dielectric region located on the substrate comprising a first dielectric layer 3, and a passivation layer 4. The dielectric region located on the substrate also comprises a membrane over an area of the etched portion of the substrate. The flow sensor also comprises a p-n junction type device formed within the dielectric membrane. The p-n junction type device is an array of three diodes in series, each diode comprising a p region 5 and an n region 6. The array of diodes is connected to metal tracks 7 for external access, and is configured to operate as a temperature sensing device. The array of diodes can also be configured to operate as a heating element.

FIG. 6 shows a schematic cross section of a CMOS flow sensor comprising: a substrate 1 comprising an etched portion obtained by dry etching and resulting in vertical sidewalls; a dielectric region located on the substrate comprising a first dielectric layer 3, and a passivation layer 4. The dielectric region located on the substrate also comprises a membrane over an area of the etched portion of the substrate. The flow sensor also comprises a p-n junction type device formed within the dielectric membrane, wherein the p-n junction type device is a diode and comprises a p region 5 and an n region 6. The diode is connected to metal tracks 7 for external access, and is configured to operate as a temperature sensing device. The array of diodes can also be configured to operate as heating element. The flow sensor also comprises additional structures within and above the dielectric region located on the substrate to engineer the thermo-mechanical properties (e.g. stiffness, temperature profile distribution, etc.) of the dielectric region and/or the fluid dynamic interaction between the fluid and the dielectric region.

FIG. 7 shows a schematic top view of a flow sensor chip 10 comprising a rectangular diode comprising a p region 5 and an n region 6 embedded within a circular membrane 8. The diode is connected to metal tracks 7 for external access, and is configured to operate as a temperature sensing device. The diode can also be configured to operate as heating element. The flow sensor chip 10 also comprises a reference p-n junction type device 11 outside the membrane 8. The reference p-n junction type device 11 can be a diode and used to measure the substrate/case/ambient temperature for compensation purposes. Any of the p-n junction type devices can also be part of a more complex temperature sensing circuit, such as a VPTAT (voltage proportional to absolute temperature) or IPTAT (current proportional to absolute temperature).

FIG. 8 shows a schematic cross section of a SOI CMOS flow sensor comprising: a substrate 1 comprising an etched portion obtained by dry etching and resulting in vertical sidewalls; a dielectric region located on the substrate comprising a first dielectric layer 2 (in a SOI process this is usually referred to as buried oxide layer, BOX), a second dielectric layer 3, and a passivation layer 4. The dielectric region located on the substrate also comprises a membrane over an area of the etched portion of the substrate. The flow sensor also comprises a p-n junction type device formed within the dielectric membrane, wherein the p-n junction type device is a diode and comprises a p region 5 and an n region 6. The diode is connected to metal tracks 7 for external access, and is configured to operate as a temperature sensing device. The flow sensor also comprises a resistor 12 formed within the dielectric membrane, wherein the resistor is configured to operate as a heating element.

FIG. 9 shows a schematic top view of a rectangular diode comprising a p region 5 and an n region 6 embedded within a circular membrane 8. The diode is connected to metal tracks 7 for external access, and is configured to operate as a temperature sensing device. The membrane 8 also comprises a resistor 12, wherein the resistor is configured to operate as a heating element. The resistor 12 is connected to metal tracks for external access, wherein the tracks are configured to allow 4-wires type measurement of the resistor 12 resistance and comprise amperometric tracks 13 and voltammetric tracks 14.

FIG. 10 shows a schematic cross section of a CMOS flow sensor comprising: a substrate 1 comprising an etched portion obtained by dry etching and resulting in vertical sidewalls; a dielectric region located on the substrate comprising a first dielectric layer 3, and a passivation layer 4. The dielectric region located on the substrate also comprises a membrane over an area of the etched portion of the substrate. The flow sensor also comprises a p-n junction type device formed within the dielectric membrane, wherein the p-n junction type device is a diode and comprises a p region 5 and an n region 6. The diode is configured to operate as a temperature sensing device. The flow sensor also comprises a resistor 12 formed within the dielectric membrane, wherein the resistor is configured to operate as heating element. The flow sensor also comprises thermopiles 15 and 16 used as additional temperature sensing elements. A thermopile comprises one or more thermocouples connected in series. Each thermocouple comprises two dissimilar materials which form a junction at a first region of the membrane, while the other ends of the materials form a junction in the heat sink region (substrate outside the membrane area), where they are connected electrically to the adjacent thermocouple or to pads for external readout.

FIG. 11 shows a schematic top view of a rectangular diode comprising a p region 5 and an n region 6 embedded within a circular membrane 8. The diode is connected to metal tracks 7 for external access, and is configured to operate as a temperature sensing device. The membrane 8 also comprises a resistor 12, wherein the resistor is configured to operate as heating element. The resistor 12 is connected to metal tracks 13 for external access. The membrane also comprises thermopiles used as additional temperature sensing elements. A thermopile comprises one or more thermocouples connected in series. Each thermocouple comprises two dissimilar materials 17 and 18 which form a junction 19 at a first region of the membrane, while the other ends of the materials form a junction 20 in the heat sink region (substrate outside the membrane area), where they are connected electrically to the adjacent thermocouple or to pads for external readout.

FIG. 12 shows a schematic top view of a rectangular diode comprising a p region 5 and an n region 6 embedded within a circular membrane 8. The diode is connected to metal tracks 7 for external access, and is configured to operate as a temperature sensing device. The membrane 8 also comprises a resistor 12, wherein the resistor is configured to operate as heating element. The resistor 12 is connected to metal tracks 13 for external access. The membrane also comprises a thermopile used as additional temperature sensing element. A thermopile comprises one or more thermocouples connected in series. Each thermocouple comprises two dissimilar materials 17 and 18 which form a junction 19 at a first region of the membrane, while the other ends of the materials form a junction 20 at a second region of the membrane, where they are connected electrically to the adjacent thermocouple or to pads for external readout.

FIG. 13 shows a schematic top view of a rectangular diode comprising a p region 5 and an n region 6 embedded within a circular membrane 8. The diode is connected to metal tracks 7 for external access, and is configured to operate as a temperature sensing device. The membrane 8 also comprises a resistor 12, wherein the resistor is configured to operate as a heating element. The resistor 12 is connected to metal tracks 13 for external access. The membrane also comprises additional p-n junction type devices formed within the membrane 8, wherein the p-n junction types device are diodes 21 configured to operate as additional temperature sensing devices.

FIG. 14 shows a schematic top view of four diodes, each comprising a p region 5 and an n region 6 embedded within a circular membrane 8. The diodes are connected to metal tracks 7 for external access, and are configured to operate as temperature sensing devices. The membrane 8 also comprises a multi ring-type resistor 12, wherein the resistor is configured to operate as heating element. The resistor 12 is connected to metal tracks 13 for external access.

FIG. 15 shows a schematic top view of two rectangular diodes, each comprising a p region 5 and an n region 6 embedded within a rectangular membrane 8 with rounded corners. The diodes are connected to metal tracks 7 for external access, and are configured to operate as temperature sensing devices. The membrane 8 also comprises two resistors 12, wherein the resistors are configured to operate as heating elements. The resistors 12 are connected to metal tracks 13 for external access.

FIG. 16 shows a schematic top view of two arrays of diodes, each formed by two rectangular diodes, each comprising a p region 5 and an n region 6 embedded within a circular membrane 8 in a cross-like arrangement. The diodes are connected to metal tracks 7 for external access, and are configured to operate as a temperature sensing devices. The membrane 8 also comprises two resistors 12 in a cross-like arrangement, wherein the resistors are configured to operate as heating elements. The resistors 12 are connected to metal tracks 13 for external access.

FIG. 17 shows a schematic top view of a rectangular diode comprising a p region 5 and an n region 6 embedded within a rectangular membrane 8 with rounded corners. The diode is connected to metal tracks 7 for external access, and is configured to operate as a temperature sensing device. The membrane 8 also comprises a resistor 12, wherein the resistor is configured to operate as heating element. The resistor 12 is connected to metal tracks 13 for external access. The membrane also comprises thermopiles used as additional temperature sensing elements. A thermopile comprises one or more thermocouples connected in series. Each thermocouple comprises two dissimilar materials 17 and 18 which form a junction 19 at a first region of the membrane, while the other ends of the materials form a junction 20 at a second region of the membrane, where they are connected electrically to the adjacent thermocouple or to pads for external readout.

FIG. 18 shows a schematic cross section of a double membrane CMOS multi sensor chip comprising: a substrate 1 comprising two etched portions obtained by dry etching and resulting in vertical sidewalls; a dielectric region located on the substrate comprising a first dielectric layer 3, and a passivation layer 4. The dielectric region located on the substrate also comprises two membranes over an area of the etched portions of the substrate. The flow sensor also comprises a p-n junction type device formed within a first dielectric membrane, wherein the p-n junction type device is a diode and comprises a p region 5 and an n region 6. The diode is configured to operate as a temperature sensing device. The flow sensor also comprises a resistor 12 formed within the first dielectric membrane, wherein the resistor is configured to operate as heating element. The flow sensor also comprises a p-n junction type device formed within a second dielectric membrane, wherein the p-n junction type device is a diode configured to operate as a temperature sensing device. The flow sensor also comprises piezo-elements 22 formed within the second dielectric membrane, wherein the piezo-elements are piezo-resistors configured to operate as pressure sensing devices.

FIG. 19 shows a schematic top view of a double membrane CMOS multi sensor chip 23. The multi sensor chip 23 comprises a first rectangular diode comprising a p region 5 and an n region 6 embedded within a first square membrane 8. The diode is connected to metal tracks 7 for external access, and is configured to operate as a temperature sensing device. The membrane 8 also comprises a zigzag-type resistor 12, wherein the resistor is configured to operate as heating element. The resistor 12 is connected to metal tracks 13 for external access. The multi sensor chip also comprises a second rectangular diode embedded within a second square membrane 24 and configured to operate as a temperature sensing device. The flow sensor also comprises piezo-elements 22 formed within the second membrane 24, wherein the piezo-elements are piezo-resistors configured to operate as pressure sensing devices.

FIG. 20 shows a schematic top view of a multi membrane CMOS multi sensor chip 25. The multi sensor chip 25 comprises a first rectangular diode comprising a p region 5 and an n region 6 embedded within a first circular membrane 8. The diode is connected to metal tracks 7 for external access, and is configured to operate as a temperature sensing device. The membrane 8 also comprises a wire-type resistor 12, wherein the resistor is configured to operate as heating element. The resistor 12 is connected to metal tracks 13 for external access. The membrane 8 also comprises a thermopile configured to operate as additional temperature sensing element. The multi sensor chip also comprises a second rectangular diode embedded within a second circular membrane 24 and configured to operate as a temperature sensing device. The membrane 24 also comprises a wire-type resistor, wherein the resistor is configured to operate as a heating element and a thermopile configured to operate as additional temperature sensing element. The multi sensor chip also comprises a third rectangular diode embedded within a first square membrane 26 and configured to operate as a temperature sensing device. The square membrane also comprises piezo-elements 22, wherein the piezo-elements are piezo-resistors configured to operate as pressure sensing devices. The multi sensor chip 25 also comprises a reference p-n junction type device 11 outside the membranes 8, 24, and 26. The reference p-n junction type device 11 can be a diode and used to measure the substrate/case/ambient temperature for compensation purposes.

FIG. 21 is an example of is an example of circuit implementing Constant Temperature Difference driving method using diode Dₕ, driven with the current generator I_{Dh}, to obtain a thermal feedback of the temperature of the heating resistor Rₕ and using diode Dₐ, driven with the current generator I_{Da}, to obtain a thermal feedback of the substrate/case/ambient for compensation purposes. The operating temperature of the heating resistor Rₕ is set through the signal V_{control}. The current in the resistor Rₕ is controlled with the transistor T, having its gate controlled by the output signal of the amplifier A2.

FIG. 22 is an example of circuital blocks that could be monolithically integrated on chip. These blocks include but are not limited to: driving circuital blocks, to drive the heating element and/or the sensing elements; substrate/case/ambient temperature sensing circuital blocks, that can be used as an input to the driving circuital blocks, as shown in FIG. 21; membranes comprising any of the sensing structures disclosed in the preferred embodiments; amplification circuital blocks to manipulate the analogue outputs of the sensing structures, the amplification circuital blocks may include amplifiers as well as filters for noise reduction or any other means to manipulate analogue signals; analogue to digital converters to allow digital processing, storage and communication of the sensing structures output. The circuital blocks can also receive data from the outside world, allowing remote control over amplification parameters, A/D conversion, driving and data stored in memory. Other circuital blocks might be included as well, such as multiplexers and de-multiplexer to select one among the many available sensing structures on chip; switches might also be integrated to switch on/off some or all circuital blocks and thus reducing power consumption.

FIG. 23 shows a schematic cross section of a CMOS flow sensor comprising: a substrate 1 comprising an etched portion obtained by dry etching and resulting in vertical sidewalls; a dielectric region located on the substrate comprising a first dielectric layer 3, and a passivation layer 4. The dielectric region located on the substrate also comprises a membrane over an area of the etched portion of the substrate. The flow sensor also comprises a p-n junction type device formed within the dielectric membrane, wherein the p-n junction type device is an array of three diodes in series, each diode comprising a p region 5 and an n region 6. The array of diodes is connected to metal tracks 7 for external access, and is configured to operate as a temperature sensing device. The array of diodes can also be configured to operate as a heating element. The flow sensor also comprises some monolithically integrated electronics herein exemplified by a MOSFET 27. The flow sensor may also comprise Through Silicon Vias (TSV) 28, thus avoiding the presence of bonding wires that could affect the flow on the device surface.

FIG. 24 is an example of a flow sensor, 3D stacked on an ASIC embedded within a PCB 29, with its surface flush with the PCB surface.

FIG. 25 is an example of sensor chip 3D stacked on a sealing substrate. The substrate may be a silicon substrate or any other substrate that allows sealing of the cavity below the sensor membrane. The substrate may also be an ASIC.

FIG. 26 illustrates an exemplary flow diagram outlining the manufacturing method of the flow sensor.

The skilled person will understand that in the preceding description and appended claims, positional terms such as ‘above’, ‘overlap’, ‘under’, ‘lateral’, etc. are made with reference to conceptual illustrations of an device, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

It will be appreciated that all doping polarities mentioned above may be reversed, the resulting devices still being in accordance with embodiments of the present invention.

Although the invention has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1. A CMOS-based flow sensor comprising:
a substrate comprising an etched portion;
a dielectric region located on the substrate, wherein the dielectric region comprises a dielectric membrane over an area of the etched portion of the substrate;
a p-n junction type device formed within the dielectric membrane, wherein the p-n junction type device is configured to operate as a temperature sensing device.

2. A flow sensor according to claim 1, wherein the p-n junction type device comprises at least one diode or an array of diodes, optionally, further comprising a heating element within the dielectric membrane.

3. (canceled)

4. A flow sensor according to claim 1, wherein the p-n junction type device comprises a transistor or an array of transistors, optionally wherein the transistor or the array of transistors comprises a diode.

5. (canceled)

6. A flow sensor according to claim 1, comprising a further p-n junction type device located outside the dielectric membrane, wherein the further p-n junction type device is configured to measure substrate temperature of the flow sensor;
and/or
wherein the p-n junction type device is operationally connected to a temperature sensing circuit.

7. (canceled)

8. A flow sensor according to claim 6, wherein the temperature sensing circuit comprises any one of a voltage proportional to absolute temperature (VPTAT) and a current proportional to absolute temperature (IPTAT).

9. A flow sensor according to claim 1, wherein the p-n junction type device is configured to operate as a heating element.

10. A flow sensor according to claim 1, further comprising a heating element within the dielectric membrane, optionally:
wherein the p-n type device is located underneath the heating element within the dielectric membrane having the relatively high increase in temperature;
and/or
wherein the heating element comprises a material comprising tungsten;
and/or
wherein the heating element comprises a material comprising any one of:
n or p type single crystal silicon;
n or p type polysilicon;
aluminium, titanium, silicides or any other metal or semi-conductive material available in a CMOS process;
and/or
wherein the heating element comprises amperometric and voltammetric connections;
and/or
comprising a further heating element which is configured to recalibrate the heating element within the dielectric membrane.

11. (canceled)

12. (canceled)

13. (canceled)

14. (canceled)

15. (canceled)

16. A flow sensor according to claim 9, wherein the p-n junction type device and/or the heating element is configured to increase temperature within the dielectric membrane, optionally wherein:
the p-n junction type device is configured to measure heat exchange between the p-n junction type device and a fluid, and the p-n junction type device is configured to correlate the heat exchange to at least one property of the fluid so as to differentiate between forms of the fluid, further optionally wherein:
the property of the fluid comprises any one of velocity, flow rate, exerted wall shear stress, pressure, temperature, direction, thermal conductivity, diffusion coefficient, density, specific heat, and kinematic viscosity.

17. (canceled)

18. (canceled)

19. A flow sensor according to claim 1, wherein the p-n type device is configured to operate in a forward bias mode in which a forward voltage across the p-n type device decreases linearly with a temperature when operated at a constant forward current.

20. A flow sensor according to claim 1, wherein the p-n type device is configured to operate in a reverse bias mode where a leakage current is exponentially dependent on a temperature.

21. A flow sensor according to claim 10, wherein the p-n type device and the heating element are configured to operate in any one of a pulse mode and a continuous mode.

22. A flow sensor according to claim 1, further comprising one or more temperature sensing elements, optionally wherein:
said one or more temperature sensing elements comprise one or more thermopiles each comprising one or more thermocouples connected in series, optionally wherein:
each thermocouple comprises two dissimilar materials which form a junction at a first region of the dielectric membrane, and the other ends of the materials form a junction at a second region of the membrane or in the heat sink region where they are electrically connected, optionally wherein either:
the thermocouple comprises a metal selected from any one of aluminium, tungsten, titanium, and a combination of these materials, and any other metal available in a CMOS process; or
the thermocouple comprises a material comprising doped polysilicon or doped single crystal silicon.

23. (canceled)

24. (canceled)

25. (canceled)

26. (canceled)

27. A flow sensor according to claim 22, wherein one temperature sensing element is configured to use for flow sensing and another temperature sensing element is configured to recalibrate said one temperature sensing element.

28. A flow sensor according to claim 22, wherein when one temperature sensing element is configured to fail, another temperature sensing element is configured to replace said one temperature sensing element.

29. A flow sensor according to claim 1, comprising a further etched portion in the substrate and a further dielectric membrane located over an area of the further etched portion of the substrate; optionally wherein:
the further dielectric membrane comprises a further p-n junction type device;
and/or
the further dielectric membrane comprises a pressure sensor comprising a piezo-element.

30. (canceled)

31. (canceled)

32. A flow sensor according to claim 1, further comprising:
circuitry formed on the same chip with said flow sensor;
and/or;
being formed with circuitry in the same package, optionally wherein:
the circuitry comprises any one of switches, multiplexer, decoder, filter, amplifier, analogue to digital converter, timing blocks, RF communications circuits, and memories;
or;
circuitry is placed outside the area of said dielectric membrane area using an application specific integrated circuit (ASIC) or a discrete component, or a combination of ASIC and the discrete component.

33. (canceled)

34. (canceled)

35. (canceled)

36. A flow sensor according to claim 1, wherein the substrate comprises any one of:
silicon;
silicon on insulator;
silicon carbide;
gallium arsenide;
gallium nitride; and/or
a combination of silicon carbide, gallium arsenide, gallium nitride with silicon.

37. A flow sensor according to claim 1, wherein the device is packaged using one or more of:
a metal transistor output (TO) type package;
a ceramic, metal or plastic surface mount package;
a flip-chip method;
a chip or wafer level package;
a printed circuitry board (PCB);
optionally wherein the package is hermetically or semi-hermetically sealed with air, dry air, argon, nitrogen, xenon or any other noble gas; and/or the device is packaged in vacuum.

38. (canceled)

39. A flow sensor according to claim 1, further comprising through silicon via (TSV) configured to implement three dimensional (3D) stacking techniques;
and/or
wherein the dielectric membrane has any one of:
a circular shape;
a rectangular shape;
a square shape; and
a rounded corner shape;
and/or
wherein the p-n junction type device has any one of a circular shape, a rectangular shape, and a hexagonal shape.

40. (canceled)

41. (canceled)

42. A method of manufacturing a CMOS-based flow sensor,
the method comprising:
forming at least one dielectric membrane on a substrate comprising an etched portion, wherein the dielectric membrane is over an area of the etched portion of the substrate;
forming a p-n junction type device within said at least one dielectric membrane, wherein the p-n junction type device operates as a temperature sensing device;
optionally wherein:
wherein said at least one dielectric membrane is formed by any one of:
back-etching using Deep Reactive Ion Etching (DRIE) of the substrate, which results in vertical sidewalls; and
using anisotropic etching such as KOH (Potassium Hydroxide) or TMAH (Tetra Methyl Ammonium Hydroxide) which results in slopping sidewalls.

43. (canceled)

44. (canceled)
